(19) United States
(12) Patent Application Publication
(10) Pub. No.: US 2022/0285251 A1
(43) Pub. Date: Sep. 8, 2022

(54) SEMICONDUCTOR PACKAGE SUBSTRATE AND METHOD OF MANUFACTURING THE SAME, AND SEMICONDUCTOR PACKAGE AND METHOD OF MANUFACTURING THE SAME

(71) Applicant: HAESUNG DS CO., LTD., Gyeongsangnam-do (KR)

(72) Inventors: Wonbin Kim, Gyeongsangnam-do (KR); Sung Il Kang, Gyeongsangnam-do (KR); In Seob Bae, Gyeongsangnam-do (KR); Dong Jin Yoon, Gyeongsangnam-do (KR)

(21) Appl. No.: 17/653,763

(22) Filed: Mar. 7, 2022

(30) Foreign Application Priority Data
Mar. 8, 2021 (KR) 10-2021-0030294

(51) Int. Cl. H01L 23/495; H01L 23/00; H01L 21/48

(52) U.S. Cl. CPC H01L 23/49548; H01L 24/48; H01L 21/4842; H01L 21/4828; H01L 23/49534; H01L 23/49582; H01L 23/49558; H01L 23/49586; H01L 2224/48245

(57) ABSTRACT

A semiconductor package substrate and a method of manufacturing the same are provided. The semiconductor package substrate includes: a base layer including a conductive material, having a first surface and a second surface opposite the first surface, and having a first groove or first trench in the first surface and a second groove or second trench in the second surface; a first resin buried in the first groove or first trench in the first surface of the base layer; and a groove in at least one corner of the first surface of the base layer and having a depth based on the first surface is 1/2 or more of a thickness of the base layer.

### CROSS-REFERENCE TO RELATED APPLICATION

This application is based on and claims priority under 35 U.S.C. § 119 to Korean Patent Application No. 10-2021-0030294, filed on Mar. 8, 2021, in the Korean Intellectual Property Office, the disclosure of which is incorporated by reference herein in its entirety.

### BACKGROUND

### 1. Field

One or more embodiments relate to a semiconductor package substrate and a method of manufacturing the same, and a semiconductor package and a method of manufacturing the same, and more particularly, to a method of manufacturing a semiconductor package substrate that is easy to solder, and a semiconductor package manufactured using the same.

### 2. Description of the Related Art

Because a semiconductor device is packaged and used in a semiconductor package substrate, the semiconductor package substrate used for such packaging has a microcircuit pattern and/or I/O terminals. As high performance and/or high integration of the semiconductor device, and miniaturization and/or high performance of an electronic device using the same, progress, a fine circuit pattern of a semiconductor package substrate has a narrower line width and a higher complexity.

When manufacturing the existing semiconductor package substrate, a through hole is formed using a copper clad laminate (CCL) laminated with copper foil, and an inner surface of the through hole is plated to electrically connect upper copper foil to lower copper foil. Afterwards, the upper copper foil and the lower copper foil are patterned using photoresist, respectively. However, the existing semiconductor package substrate manufacturing method has a problem in that a manufacturing process is complicated and precision is low.

Accordingly, in recent years, in order to simplify the manufacturing process, a method of manufacturing a semiconductor package substrate by filling an insulating material in a conductive base layer has been introduced.

### SUMMARY

One or more embodiments include a semiconductor package substrate that is easy to solder and a method of manufacturing the same. However, this is merely an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a semiconductor package substrate includes: a base layer including a conductive material, having a first surface and a second surface opposite the first surface, and having a first groove or first trench in the first surface and a second groove or second trench in the second surface; a first resin buried in the first groove or first trench in the first surface of the base layer; and a groove structure in at least one corner of the first surface of the base layer and having a depth based on the first surface is ½ or more of a thickness of the base layer.

In the present embodiment, a depth of the groove structure may be 100 μm or more.

In the present embodiment, a thickness of the base layer corresponding to the groove structure may be 35 μm or more.

In the present embodiment, a width of the base layer with respect to the first surface corresponding to the groove may be 30 μm or more greater than a width of the groove structure with respect to the second surface.

In the present embodiment, the semiconductor package substrate may further include a coating layer disposed on a surface of the base layer except for the first resin.

In the present embodiment, at least a portion of the first resin may be exposed to the outside through the groove structure.

In the present embodiment, the semiconductor package substrate may further include a second resin buried in the second groove or second trench in the second surface of the base layer.

In the present embodiment, the width of the base layer with respect to the first surface corresponding to the groove structure may be the same as the width of the groove structure with respect to the second surface.

According to one or more embodiments, a semiconductor package includes: a semiconductor package substrate; and a semiconductor chip mounted on the semiconductor package substrate.

According to one or more embodiments, a method of manufacturing a semiconductor package substrate, the method includes: preparing a base layer of a conductive material having a first surface and a second surface; forming a first groove or first trench in a first surface of the base layer; filling the first groove or first trench with a first resin; curing the first resin; removing a portion of the first resin that is exposed to the outside of the first groove or first trench and overfilled; forming a second groove or second trench in the second surface of the base layer to expose at least a portion of the first resin filled in the first groove or first trench; and forming a third groove in the first surface of the base layer, wherein a depth of the third groove is at least ½ of a thickness of the base layer.

In the present embodiment, the forming of the second groove or second trench in the base layer may be simultaneously performed with the forming of the third groove.

In the present embodiment, the third groove may have a width in a first direction and a length in a second direction intersecting with the first direction, and a width of a cutting area may be less than a length of the third groove.

In the present embodiment, the third groove may have a depth of 100 μm or more.

In the present embodiment, the thickness of the base layer corresponding to the third groove may be 35 μm or more.

In the present embodiment, a width of the base layer corresponding to the third groove as viewed from the second surface may be equal to or greater than a width of the third groove as viewed from the first surface with respect to one side.

In the present embodiment, at least a portion of the first resin may be exposed to the outside through the third groove.

In the present embodiment, the method may further include: filling the second groove or second trench with a second resin between the forming of the second groove or second trench in the second surface of the base layer to expose at least a portion of the first resin filled in the first groove or first trench and the forming of the third groove in the first surface of the base layer.

In the present embodiment, the width of the base layer with respect to the first surface corresponding to the third groove may be the same as the width of the third groove with respect to the second surface.

In the present embodiment, the method may further include: forming a coating layer by plating a surface of the base layer exposed through the first surface and the second surface between the forming of the third groove in the first surface of the base layer and cutting the base layer along a cutting area passing through the center of the third groove.

According to one or more embodiments, a method of manufacturing a semiconductor package substrate, the method includes: mounting a semiconductor chip on a semiconductor package substrate; and cutting the semiconductor package substrate along a third groove.

Additional aspects will be set forth in part in the description which follows and, in part, will be apparent from the description, or may be learned by practice of the presented embodiments.

These general and specific embodiments may be implemented by using a system, a method, a computer program, or a combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 5 are cross-sectional views schematically illustrating some processes of a method of manufacturing a semiconductor package substrate, according to an embodiment;

FIG. 6 is a rear view of the semiconductor package substrate of FIG. 5;

FIG. 7 is a cross-sectional view schematically illustrating a cross-section of a third groove H3, taken along line A-A′ in FIG. 6;

FIG. 8 is a cross-sectional view schematically illustrating a cross-section of the third groove H3, taken along line B-B′ in FIG. 6;

FIG. 9 is a cross-sectional view schematically illustrating some processes of a method of manufacturing a semiconductor package substrate, according to an embodiment;

FIGS. 10 to 12 are cross-sectional views schematically illustrating manufacturing processes for forming a semiconductor package by using a semiconductor package substrate after forming the semiconductor package substrate;

FIGS. 13A to 13C are cross-sectional views schematically illustrating a method of manufacturing a semiconductor package substrate, according to another embodiment;

FIG. 14 is a cross-sectional view schematically illustrating a semiconductor package including a semiconductor package substrate according to an embodiment;

FIG. 15 is a perspective view schematically illustrating a groove of a semiconductor package substrate according to an embodiment; and

FIG. 16 is a cross-sectional view schematically illustrating a semiconductor package including a semiconductor package substrate according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Since the disclosure may have diverse modified embodiments, preferred embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

Reference will now be made in detail to embodiments, examples of which are illustrated in the accompanying drawings, wherein like reference numerals refer to like elements throughout, and repeated description thereof will be omitted.

It will be understood that although the terms “first,” “second,” etc. may be used herein to describe various elements, these elements should not be limited by these terms.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or component is referred to as being “formed on” another layer, region, or component, it can be directly or indirectly formed on the other layer, region, or component. That is, for example, intervening layers, regions, or components may be present.

It will be understood that when a layer, region, or component is connected to another portion, the layer, region, or component may be directly connected to the portion, and/or an intervening layer, region, or component may exist, such that the layer, region, or component may be indirectly connected to the portion. For example, when a layer, region, or component is electrically connected to another portion, the layer, region, or component may be directly electrically connected to the portion and/or may be indirectly connected to the portion through another layer, region, or component.

In the specification, the term “A and/or B” refers to the case of A or B, or A and B. In the specification, the term “at least one of A and B” refers to the case of A or B, or A and B.

As used herein, an x-axis, a y-axis and a z-axis are not limited to three axes of a rectangular coordinate system and may be interpreted in a broader sense. For example, the x-axis, the y-axis, and the z-axis may be perpendicular to one another, or may represent different directions that are not perpendicular to one another.

In the specification, when a certain embodiment may be implemented differently, a specific process order may be performed differently from the described order. For example, two consecutively described processes may be performed substantially at the same time or performed in an order opposite to the described order.

Sizes of elements in the drawings may be exaggerated for convenience of description. In other words, since sizes and thicknesses of components in the drawings are arbitrarily illustrated for convenience of description, the following embodiments are not limited thereto.

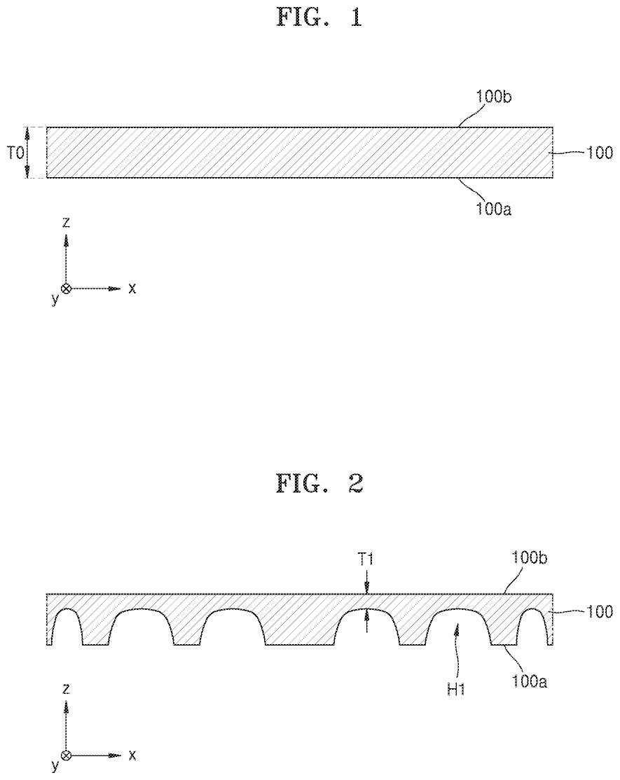

FIGS. 1 to 5 are cross-sectional views schematically illustrating some processes of a method of manufacturing a semiconductor package substrate, according to an embodiment.

First, referring to FIG. 1, a base layer 100 made of a conductive material is prepared according to the method of manufacturing a semiconductor package substrate 10 according to the present embodiment. The base layer 100 may have a flat plate shape including an electrically conductive material. The electrically conductive material may include, for example, Fe, an Fe alloy such as Fe—Ni or Fe—Ni—Co, Cu, or a Cu alloy such as Cu—Sn, Cu—Zr, Cu—Fe, or Cu—Zn.

The base layer 100 may have a first surface 100a and a second surface 100b facing opposite to each other in a plate shape. The first surface 100a is a rear surface and refers to a surface disposed to face the ground, and the second surface 100b is an upper surface and refers to a surface opposite to the first surface 100a.

In an embodiment, a thickness T0 of the base layer 100 may be about 100 μm to 500 μm, for example, about 185 μm to about 200 μm.

Thereafter, referring to FIG. 2, a first groove or first trench H1 is formed in the first surface 100a of the base layer 100. The first groove or first trench H1 means that the first groove or first trench H1 does not completely penetrate the base layer 100. FIG. 2 is a cross-sectional view, but a portion excluding the first groove or first trench H1 of the first surface 100a of the base layer 100 may be understood as a wiring pattern extending in a preset direction or meandering in a plan view.

In order to form the first groove or first trench H1, a dry film resist (DFR) made of a photosensitive material is laminated on the first surface 100a of the base layer 100, and through processes, such as exposure and development, only a portion of the base layer 100, in which the first groove or first trench H1 is to be formed, is exposed. Thereafter, by etching a portion of the first surface 100a of the base layer 100 that is not covered with the DFR by using an etchant such as copper chloride or iron chloride, the first groove or first trench H1 may be formed in the first surface 100a thereof so as not to penetrate the base layer 100, as shown in FIG. 2.

A portion that is not removed from the first surface 100a of the base layer 100, that is, a portion other than the first groove or first trench H1, may serve as a wiring pattern later. Therefore, when the first groove or first trench H1 is formed in the first surface 100a of the base layer 100, a width of a portion between adjacent grooves or between trenches is preferably set to about 20 μm to about 30 μm, which is a width of a typical wiring pattern.

When the first groove or first trench H1 is formed in the first surface 100a of the base layer 100 as shown in FIG. 2, a depth of the first groove or first trench H1 is preferably about 80% to about 90% of the thickness of the base layer 100, but the disclosure is not necessarily limited thereto.

When the depth of the first groove or first trench H1 is greater than this, it may not be easy to handle the base layer 100 or the semiconductor package substrate 100 during a semiconductor package substrate manufacturing process or a subsequent packaging process. In addition, when the depth of the first groove or first trench H1 is greater than this, in some cases, a through hole passing through the first surface 100a and the second surface 100b of the base layer 100 may be formed due to a tolerance in forming the first groove or first trench H1. On the other hand, when the depth of the first groove or first trench H1 is less than this, this may make a subsequent process difficult when manufacturing a semiconductor package substrate in the future, or a thickness of a finally manufactured semiconductor package substrate may be too thin.

In an embodiment, the base layer 100 including copper (Cu) or a Cu-alloy as a main component may be etched using an etchant through a spraying method. In this case, the first surface 100a thereof is half-etched to implement a target shape on a Cu or Cu-alloy material. In addition, in order to prevent deformation of the material and to prevent penetration of the base layer 100 by etching, a remaining thickness T1 of the base layer 100 corresponding to the first groove or first trench H1 is preferably formed to be at least 35 μm or more.

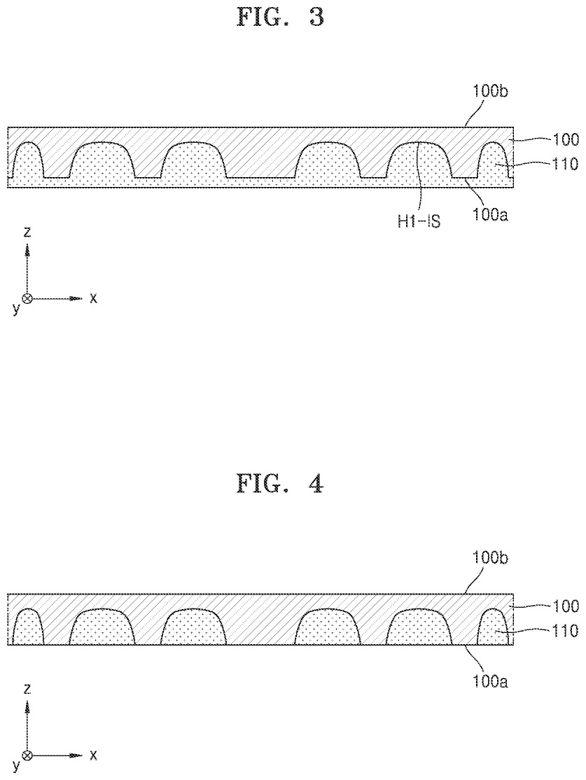

Thereafter, referring to FIG. 3, the first groove or first trench H1 of the base layer 100 is filled with a first resin 110. The first resin 110 may be made of an insulating material that is not electrically conductive. For example, the first resin 110 may be a thermosetting resin that is polymerized and cured by heat treatment. The first resin 110 electrically insulates between wiring patterns of the semiconductor package substrate later. The first resin 110 may be filled using a liquid material, or using a solid tape containing a component of the first resin 110, or using a powder including a resin component.

On the other hand, although not shown, in order to promote adhesion between the first resin 110 and an inner surface H1-IS of the first groove or first trench H1, a process of increasing surface roughness or a surface area by a chemical method (e.g., plating, etching, etc.) or a physical method (e.g., polishing, etc.) may be added to the entire surface of the entire inner surface H1-IS of the first groove or first trench H1 before filling the first resin 110. Through this, the first resin 110 filled in the first groove or first trench H1 of the first surface 100a thereof may have high uniformity (less voids) and excellent adhesion.

In more detail, before filling the first resin 110 in the first groove or first trench H1 of the base layer 100, the inner surface H1-IS of the first groove or first trench H1 may be roughened. Through this, a bonding force between the first resin 110 and the base layer 100 may be remarkably increased. In order to roughen the inner surface H1-IS of the first groove or first trench H1 of the base layer 100, plasma treatment, UV treatment, or a persulphuric acid solution may be used. In this case, the roughness of the inner surface H1-IS of the first groove or first trench H1 of the base layer 100 may be about 150 nm or more.

Thereafter, after filling the first resin 110, the temperature of the first resin 110 is raised to undergo a curing process. In particular, in the case of a liquid resin, a time spent in a horizontal section to prevent the resin from dripping during the curing process may be increased.

Thereafter, referring to FIG. 4, when the first resin 110 is over-applied, the over-applied portion of the first resin 110 may be removed.

When filling with the first resin 110, as shown in FIG. 3, the first resin 110 may not only fill the first groove or first trench H1 of the base layer 100, but may also cover at least a portion of the first surface 100a of the base layer 100. At this time, by removing the first resin 110 over-applied on the first surface 100a, the first resin 110 may be located only in the first groove or first trench H1 of the base layer 100.

The over-applied first resin 110 may be removed by, for example, mechanical processing such as laser, brushing, grinding, or polishing, or may be removed by chemical etching of the first resin 110. As such, as a portion of the first resin 110 covering at least a portion of the first surface 100a of the base layer 100 is removed, the first surface 100a of the base layer 100 may be exposed to the outside again.

However, the removing of the over-applied first resin 110 may be omitted. In other words, when filling with the first resin 110, it may be considered that only the first groove or first trench H1 of the base layer 100 is filled, as shown in FIG. 4, instead of overfilling the first resin 110, as shown in FIG. 3. However, in this case, there is a problem that the first groove or first trench H1 of the base layer 100 may not be properly filled with the first resin 110.

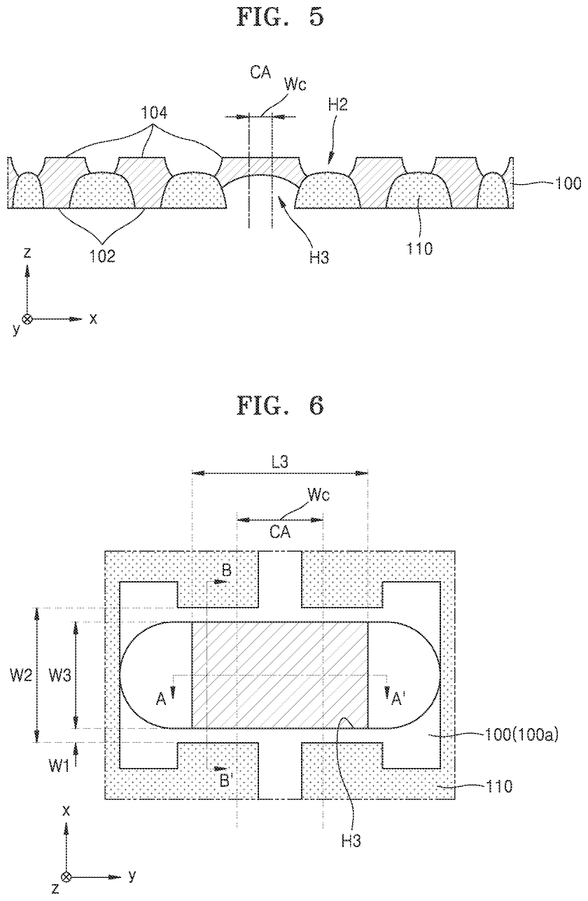

Thereafter, referring to FIG. 5, a second groove or second trench H2 is formed by etching the second surface 100b of the base layer 100 to expose the first resin 110 filling the first groove or first trench H1.

The second surface 100b of the base layer 100 may be etched through various methods, and in general, this may be the same as the etching of the first surface 100a of the base layer 100 as described above with reference to FIG. 2. For example, a DFR of a photosensitive material is laminated on the second surface 100b of the base layer 100, and only a portion to be etched of the second surface 100b of the base layer 100 is exposed through a process such as exposure and development. Thereafter, by etching a portion of the second surface 100b of the base layer 100 that is not covered with the DFR by using an etchant such as copper chloride or iron chloride, as shown in FIG. 5, at least a portion of the first resin 110 may be exposed on the second surface 100b of the base layer 100.

According to this process, a first conductive pattern 102 between first resins 110 also appears on the first surface 100a of the base layer 100, and a second conductive pattern 104 between the first resins 110 appears on the second surface 100b of the base layer 100. In the case of a semiconductor package substrate, the second conductive pattern 104 on the second surface 100b thereof is electrically connected to the first conductive pattern 102 on the first surface 100a thereof, and thus, conductive layer patterning of the second surface 100b and conductive layer patterning of the first surface 100a need to be performed as preset.

At the same time, the third groove H3 is formed in the first surface 100a of the base layer 100.

The third groove H3 may be formed where the first groove or first trench H1 is not formed, that is, between the first grooves or first trenches H1. In a manufacturing process, the third groove H3 is formed after the first resin 110 is filled in the first groove or first trench H1, and it may be understood that the third groove H3 is formed while the first resin 110 is formed. The third groove H3 may be used as a wettable flank structure to facilitate soldering of a semiconductor package later.

In the present embodiment, the third groove H3 is also formed so as not to completely penetrate the base layer 100, like the first groove or first trench H1. In an embodiment, a depth D of the third groove H3 may be about 100 μm or more. As described later in detail, the third groove H3 is used as a wettable flank structure for soldering a semiconductor package substrate to a printed circuit board PCB (FIG. 16). Therefore, in order to improve the reliability of a soldering structure and facilitate the process, it is preferable that the depth D of the third groove H3 of the soldering area is about 100 μm or more. However, in another embodiment, when the original thickness T0 of the base layer 100 is about 185 μm or less, the depth D of the third groove H3 may be about ½ of the thickness T0 of the base layer 100. Through this, the semiconductor package substrate may secure sufficient soldering wettability.

The third groove H3 may be formed to correspond to a cutting area CA. For example, the third groove H3 may be formed in one direction (e.g., a y-direction) and the other direction (e.g., an x-direction) orthogonal to the one direction.

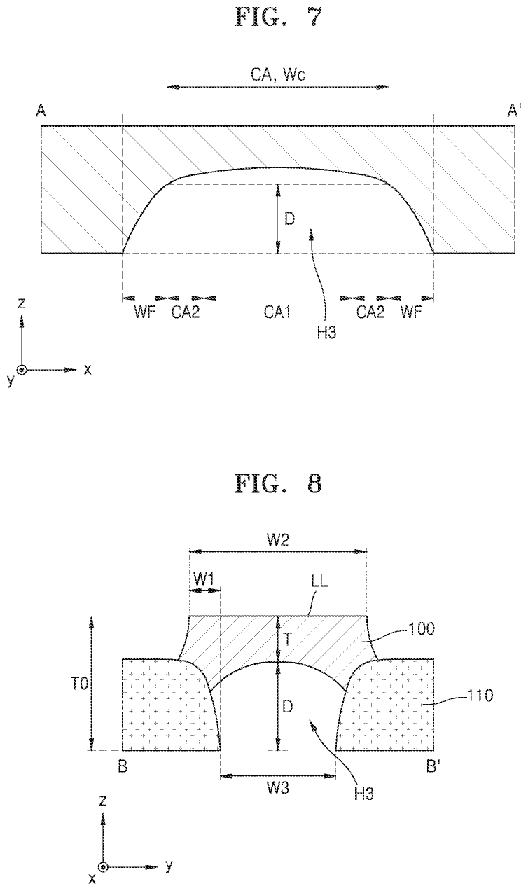

FIG. 6 is a rear view of the semiconductor package substrate of FIG. 5, FIG. 7 is a cross-sectional view schematically illustrating a cross-section of the third groove H3, taken along line A-A′ in FIG. 6, and FIG. 8 is a cross-sectional view schematically illustrating a cross-section of the third groove H3, taken along line B-B′ in FIG. 6.

Referring to FIGS. 5 and 6 together, the third groove H3 may be formed to correspond to the cutting area CA. The third groove H3 may be defined by a length L3 in one direction (e.g., the y-direction) and a width W3 in the other direction (e.g., the x-direction).

In this case, the length L3 of the third groove H3 is formed to be greater than a width Wc of the cutting area CA. When the length L3 of the third groove H3 is equal to or less than the width Wc of the cutting area CA, because the third groove H3 cannot be used as a wettable flank structure after a semiconductor package substrate is cut, it is important that the length L3 of the third groove H3 is greater than the width Wc of the cutting area CA.

The width Wc of the cutting area CA is defined by a cutting line CA1 and a cutting tolerance CA2. Because the cutting tolerance CA2 is located on both sides of the cutting line CA1, the cutting area CA satisfies the following Equation 1.

Width Wc of cutting area CA=(Width of cutting line CA1+Width of cutting tolerance CA2)*2 [Equation 1]

Accordingly, the length L3 of the third groove H3 may be defined by the following Equation 2.

Length L3 of third groove H3=(Width Wc of cutting area CA+Width of groove WF)*2 [Equation 2]

The depth D of the third groove H3 described above may be defined as a maximum value of the depth D of the groove structure WF excluding the cutting area CA. The groove structure WF of FIG. 7 may be used as a wettable flank structure after a semiconductor package substrate is cut.

Referring to FIG. 8, the depth D of the groove structure WF may be defined as a maximum value of the groove structure WF illustrated in FIG. 8.

In an embodiment, the depth D of the groove structure WF may be about 100 μm or more. In another embodiment, when the original thickness TO of the base layer 100 is about 185 μm or less, the depth D of the groove structure WF may be about ½ of the thickness T0 of the base layer 100. In summary, when the original thickness T0 of the base layer 100 is greater than about 185 μm, the depth D of the groove structure WF may be formed to be about 100 μm or more, and when the original thickness T0 of the base layer 100 is about 185 μm or less, the depth D of the groove structure WF may be about ½ of the thickness T0 of the base layer 100. In other words, when the original thickness T0 of the base layer 100 is about 185 m or less and the depth D of the groove structure WF is about 100 μm or more, because the remaining thickness T1 of the base layer 100 corresponding to the groove structure WF is too thin, it is not easy to proceed with the subsequent process.

The remaining thickness T1 of the base layer 100 corresponding to the groove structure WF may be about 35 μm or more. The numerical value may mean a minimum value of the remaining thickness T1 of the base layer 100. In other words, when the remaining thickness T1 of the base layer 100 is about 35 μm or more, a semiconductor package substrate may proceed with the subsequent process. When the remaining thickness T1 of the base layer 100 is less than about 35 μm, because the semiconductor package substrate is cut during the subsequent process or the third groove H3 penetrates the base layer 100, there is a high probability that a defect occurs.

In an embodiment, a width W2 of the base layer 100 viewed from the second surface 100b may be formed to be greater than a width W3 of the third groove H3 viewed from a first surface 100b, and a tolerance W1 with respect to one side may be at least 30 μm or more. That is, the width W2 of the base layer 100 viewed from the second surface 100b may be formed to be 30 μm or more greater than the width W3 of the third groove H3 viewed from the first surface 100b with respect to one side.

Because a semiconductor package substrate according to an embodiment has a structure in which a corresponding portion is filled with a resin through two etching processes of etching both sides thereof, the width W3 of the third groove H3 may be implemented to be substantially similar to a width (land width) of the second surface 100b at a maximum depth by reducing the possibility of penetration of the base layer 100. Accordingly, a structure in which at least a portion of the first resin 110 is exposed through the third groove H3 may be possible.

In this case, to prevent double-sided etching of the base layer 100, penetration due to misalignment due to the double-sided etching, or mold leakage, etc., the width W3 of the third groove H3 is preferably formed to be at least 30 μm greater on one side than the width of the second surface 100b, that is, a width of a lead land LL.

On the other hand, referring back to FIG. 5, in the method of manufacturing a semiconductor package substrate, according to an embodiment, the third groove H3 may be formed in the first surface 100a of the base layer 100 while the second groove or second trench H2 is formed in the second surface 100b of the base layer 100. In other words, double-sided etching may be performed on the second surface 100b and the first surface 100a of the base layer 100 at the same time. Therefore, the third groove H3 may be formed in the first surface 100a of the base layer 100 while the second groove or second trench H2 is formed without the need for an additional process for forming the third groove H3. The third groove H3 is formed after the first resin 110 is filled in the base layer 100, and an area in which the third groove H3 is formed is surrounded and locked by the first resin 110 already filled, so that the third groove H3 may be formed to have a desired width and depth.

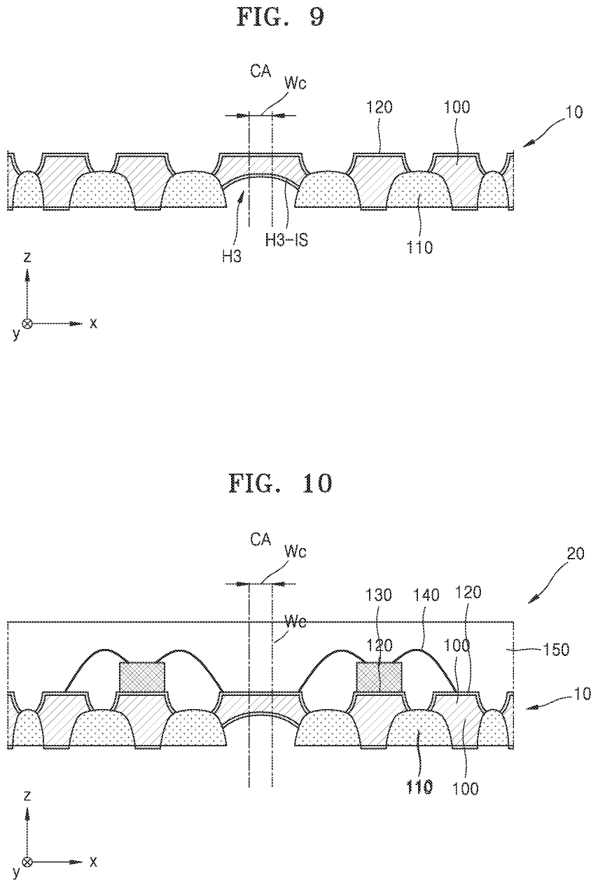

Thereafter, referring to FIG. 9, a plating layer 120 may be formed on at least a portion of the remaining portion of the base layer 100. The plating layer 120 may be formed on an inner surface H3-IS of the third groove H3, and in some cases, may be formed on the first surface 100a, the second surface 100b, or an inner surface of the first groove or first trench H1 of the base layer 100 except for the first resin 110. In particular, the plating layer 120 formed on the inner surface H3-IS of the third groove H3 may improve solder wettability of the semiconductor package substrate 10.

The plating layer 120 may be formed by plating using, for example, Au, Pd, NiPd, Au-Alloy, or the like. An organic layer coating such as an organic solderability preservative (OSP) or a method such as anti-tarnish may be used on the second surface 100b of the base layer 100.

As described above, by forming the third groove H3 in the process of manufacturing a semiconductor package substrate, soldering of a semiconductor package may be facilitated.

As a comparative example, in soldering a semiconductor package substrate, it may be assumed that a groove is formed in a soldering portion by simply soldering the semiconductor package substrate to a right-angled corner or through a separate process after packaging a semiconductor chip. However, when the semiconductor package substrate is simply soldered to the right-angled corner, the solder wettability is significantly deteriorated, and when a groove is formed in the soldering portion through a separate process, there is a problem in that a metal burr is generated in the process of forming the groove structure, thereby degrading the quality of the semiconductor package.

Accordingly, in a method of manufacturing a semiconductor package substrate, according to an embodiment, as the third groove H3 for a wettable flank structure is formed corresponding to the cutting area CA without adding a separate process when manufacturing a semiconductor package substrate, that is, a lead frame, after packaging a semiconductor chip, a wettable flank structure may be efficiently formed without adding a separate process.

FIGS. 10 to 12 are cross-sectional views schematically illustrating manufacturing processes for forming a semiconductor package by using a semiconductor package substrate after forming the semiconductor package substrate.

The processes of FIGS. 10 to 12 may be performed separately or continuously from the process of FIG. 9 described above.

Referring to FIGS. 10 to 12 following FIG. 9, a semiconductor chip 130 is mounted on the semiconductor package substrate 10 manufactured through the manufacturing processes of FIGS. 1 to 9 described above. The semiconductor chip 130 may be mounted on a flat portion of an upper surface of the semiconductor package substrate 10, and the semiconductor chip 130 may be electrically and physically connected to a lead of the base layer 100 by a wire 140. The wire 140 may be connected to the semiconductor chip 130 and the lead by wire bonding. One side of the wire 140 is attached to the lead, and the other side of the wire 140 is connected to the semiconductor chip 130.

A molding layer 150 may be formed on the semiconductor chip 130 mounted on the semiconductor package substrate 10. The molding layer 150 may seal the semiconductor chip 130 from the outside, and may be formed of, for example, a single molding structure, a double molding structure, or a triple or more molding structure. The molding layer 150 may be formed by curing, for example, a resin, and may include, for example, at least one of a phosphor and a light diffusing material. In some cases, a light-transmitting material that does not include a phosphor and a light diffusing material may be used.

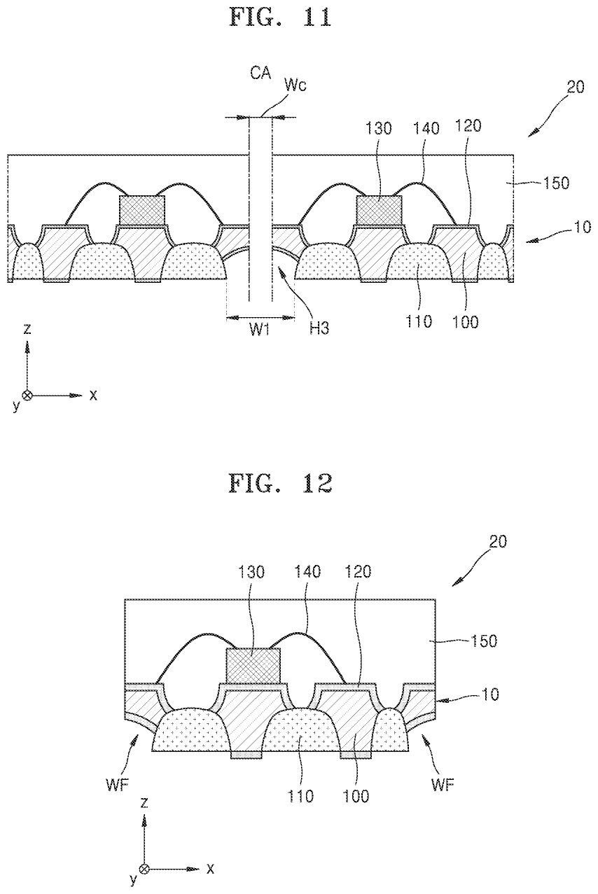

After the semiconductor chip 130 is mounted on the semiconductor package substrate 10, the base layer 100 is cut, as shown in FIG. 11. Cutting the base layer 100 may be understood as cutting the semiconductor package substrate 10 filled with the first resin 110. As shown in FIG. 8, the base layer 100 may be cut along the cutting area CA formed along the third groove H3. As described above, the length L3 of the third groove H3 may be greater than the width We of the cutting area CA. Therefore, after cutting, as shown in FIG. 12, the semiconductor package substrate 10 is provided with the groove structure WF having a wettable flank structure in which one corner of the lower end of the groove structure WF is recessed. Through this, solder wettability of the semiconductor package substrate 10 may be improved.

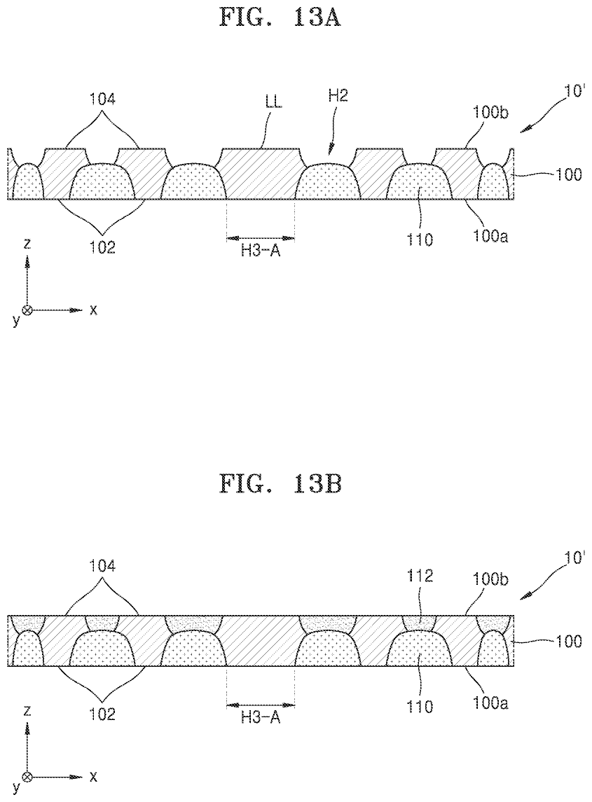

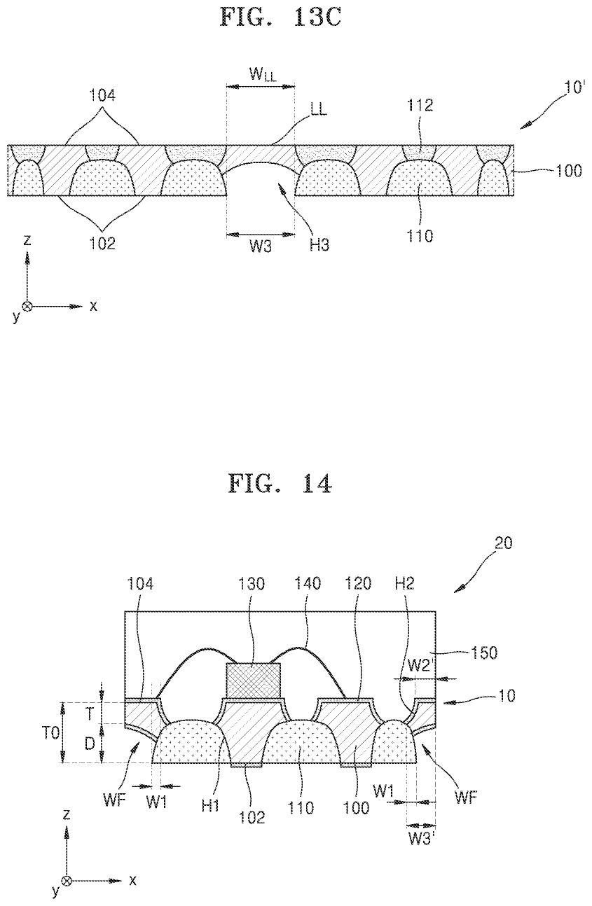

FIGS. 13A to 13C are cross-sectional views schematically illustrating a method of manufacturing a semiconductor package substrate, according to another embodiment.

A manufacturing process according to the present embodiment may be used when it is difficult to form the third groove H3 in the first surface 100a of the base layer 100 at the same time when the second groove or second trench H2 is formed in the second surface 100b of the base layer 100 as in the process of FIG. 5 described above. That is, in FIGS. 13A to 13C, forming the second groove or second trench H2 in the second surface 100b of the base layer 100 and forming the third groove H3 in the first surface 100a of the base layer 100 may be performed separately. The processes of FIGS. 13A to 13C may be used when the thickness T0 of the base layer 100 is thin or when it is difficult to ensure that the tolerance W1 between the third groove H3 and the lead land LL is 30 μm as in FIG. 8 described above.

Referring first to FIG. 13A, FIG. 13A may be performed following the process of FIG. 4. After filling the first resin 110 on the first surface 100a of the base layer 100, as shown in FIG. 4, as shown in FIG. 13A, the second groove or second trench H2 may be formed in the second surface 100b of the base layer 100. In this case, unlike FIG. 5, the third groove H3 is not formed in the first surface 100a of the base layer 100.

Thereafter, referring to FIG. 13B, a second resin 112 may be filled in the second groove or second trench H2. The second resin 112 may be the same material as the first resin 110 or a different material from the first resin 110. A method of filling with the second resin 112 may be the same as a method of filling with the first resin 110. Although not shown, after the second resin 112 is overfilled, the remaining portion may be removed.

In the present embodiment, the first resin 110 and the second resin 112 may penetrate the base layer 100 and contact each other.

Thereafter, referring to FIG. 13C, the third groove H3 may be formed in a third groove area H3-A of the first surface 100a of the base layer 100. The position and shape of the third groove H3 are the same as those described with reference to FIG. 5.

In the present embodiment, the width W3 of the third groove H3 may be the same as a width W_{LL} of the lead land LL. As such, in FIGS. 13A to 13C, by separately performing the process of forming the second groove or second trench H2 in the second surface 100b of the base layer 100 and the process of forming the third groove H3 in the first surface 100a of the base layer 100, when the thickness T0 of the base layer 100 is thin or when it is difficult to secure the tolerance W1 between the third groove H3 and the lead land LL of 30 μm, a design limitation may be overcome.

Up to this point, only a method of manufacturing a semiconductor package substrate and a method of manufacturing a semiconductor package have been mainly described, but the disclosure is not limited thereto. For example, a semiconductor package substrate manufactured using the method of manufacturing a semiconductor package substrate, and a semiconductor package including the semiconductor package substrate may be considered to be within the scope of the disclosure.

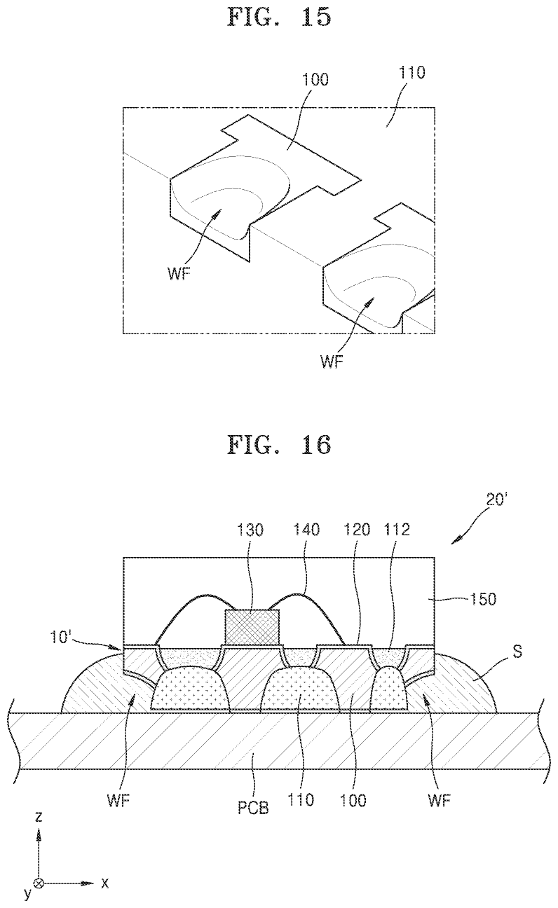

FIG. 14 is a cross-sectional view schematically illustrating a semiconductor package including a semiconductor package substrate according to an embodiment, and FIG. 15 is a perspective view schematically illustrating a groove of a semiconductor package substrate according to an embodiment.

Referring to FIGS. 14 and 15, the semiconductor package substrate 10 according to an embodiment includes the base layer 100, the first resin 110 buried in the first surface 100a of the base layer 100, and the groove structure WF.

The base layer 100 may have a flat plate shape including an electrically conductive material. The electrically conductive material may include, for example, Fe, an Fe alloy such as Fe—Ni or Fe—Ni—Co, Cu, or a Cu alloy such as Cu—Sn, Cu—Zr, Cu—Fe, or Cu—Zn. The base layer 100 may have the first surface 100a and the second surface 100b facing opposite to each other in a plate shape.

The first groove or first trench H1 may be provided in the first surface 100a of the base layer 100, and the first resin 110 may be filled in the first groove or first trench H1. The first resin 110 may be filled up to the same level as the first surface 100a of the base layer 100, so that the first surface 100a of the base layer 100 may form a planarized surface.

The second groove or second trench H2 may be provided in the second surface 100b of the base layer 100. The second groove or second trench H2 may be etched up to a portion where the first resin 110 is formed on the opposite side, and at least a portion of the first resin 110 buried in the first surface 100a thereof may be exposed through the second groove or second trench H2.

A first conductive pattern 102 is formed on the first surface 100a of the base layer 100 by the first groove or first trench H1 and the first resin 110 filled therebetween, and the second conductive pattern 104 is formed on the second surface 100b of the base layer 100 by the second groove or second trench H2 and the first resin 110 exposed therethrough.

The groove structure WF may be located at one corner of the first surface 100a of the base layer 100. The groove structure WF may have a shape in which one corner of the base layer 100 is recessed toward the base layer 100 as shown in FIG. 15. A plurality of grooves WF may be provided at one corner of the first surface 100a of the base layer 100. As described above, by forming the groove structure WF in the semiconductor package substrate 10, soldering of the semiconductor package may be facilitated.

In an embodiment, the depth D of the groove structure WF may be 100 μm or more. At this time, the depth D of the groove structure WF is a depth D measured with respect to the first surface 100a of the base layer 100, and may be defined as a maximum depth of the groove structure WF having a half arc shape by etching. Accordingly, the depth D of the groove structure WF may have a maximum value on the same surface as a side surface 100c of the base layer 100.

In another embodiment, when the original thickness TO of the base layer 100 is about 185 μm or less, the depth D of the third groove WF may be about ½ of the thickness T0 of the base layer 100. Through this, defects during the process of the semiconductor package substrate may be minimized.

In an embodiment, the remaining thickness T1 of the base layer 100 corresponding to the groove structure WF may be about 35 μm or more. The numerical value may mean a minimum value of the remaining thickness T1 of the base layer 100. In other words, when the remaining thickness T of the base layer 100 is about 35 μm or more, the semiconductor package substrate may proceed with the subsequent process. When the remaining thickness T1 of the base layer 100 is less than about 35 μm, because the semiconductor package substrate is cut during the subsequent process or the groove structure WF penetrates the base layer 100, there is a high probability that a defect occurs.

In an embodiment, a width W2′ of the base layer 100 viewed from the second surface 100b may be formed to be greater than a width W3′ of the groove structure WF viewed from the first surface 100b, and the tolerance W1 with respect to one side may be at least 30 μm or more. That is, the width W2′ of the base layer 100 viewed from the second surface 100b may be formed to be 30 μm or greater than the width W3′ of the groove structure WF viewed from the first surface 100b with respect to one side.

The plating layer 120 may be on a surface of the base layer 100. The plating layer 120 may be formed on an inner surface of the groove structure WF, and in some cases, may be formed on the first surface 100a, the second surface 100b, or the inner surface of the first groove or first trench H1 of the base layer 100 except for the first resin 110. In particular, the plating layer 120 formed on the inner surface of the groove structure WF may improve solder wettability of the semiconductor package substrate 10.

The plating layer 120 may be formed by plating using, for example, Au, Pd, NiPd, Au-Alloy, or the like. An organic layer coating such as an OSP or a method such as anti-tarnish may be used on the second surface 100b of the base layer 100.

Although the depth D of the groove structure WF may be somewhat reduced by the plating layer 120, a thickness of the plating layer 120 is several μm, which is not a factor that substantially affects the depth D of the groove structure WF. In addition, because the plating layer 120 is also formed on the first surface 100a of the base layer 100, when soldering the plating layer 120 with a solder material S to the printed circuit board PCB, as shown in FIG. 16, the depth D of the groove structure WF may be compensated for by a thickness of the plating layer 120 formed on the inner surface of the groove structure WF.

FIG. 16 is a cross-sectional view schematically illustrating a semiconductor package including a semiconductor package substrate according to an embodiment.

Referring to FIG. 16, a semiconductor package 20′ including a semiconductor package substrate 10′ formed through the manufacturing processes of FIGS. 13A to 13C is shown. Because the semiconductor package substrate 10′ of FIG. 16 is the same as in FIGS. 13A to 13C described above, the description above applies also here.

The second resin 112 embedded in the second surface 100b of the base layer 100 is provided on the semiconductor package substrate 10′ of FIG. 16. The second groove or second trench H2 is provided in the second surface 100b of the base layer 100, and the second resin 112 may be filled in the second groove or second trench H2. The second resin 112 may be filled up to the same level as the second surface 100b of the base layer 100 so that the second surface 100b of the base layer 100 may form a planarized surface.

Furthermore, the semiconductor package 20′ of FIG. 16 may be soldered onto a printed circuit board PCB using a solder material S. The solder material S is directly formed in the groove structure WF, and may be in direct contact with the printed circuit board PCB.

Because the semiconductor package substrate 10′ according to an embodiment and the semiconductor package 20′ including the same include the groove structure WF having a depth D of 100 μm or more, it is possible to minimize a defect rate during soldering, thereby enabling efficient and stable soldering.

According to an embodiment of the disclosure as described above, a semiconductor package substrate that is easy to solder and a method of manufacturing the same may be implemented. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A semiconductor package substrate comprising:
a base layer including a conductive material, having a first surface and a second surface opposite the first surface, and having a first groove or first trench in the first surface and a second groove or second trench in the second surface;
a first resin buried in the first groove or first trench in the first surface of the base layer; and
a groove structure in at least one corner of the first surface of the base layer and having a depth based on the first surface of the base layer is ½ or more of a thickness of the base layer.

2. The semiconductor package substrate of claim 1, wherein a depth of the groove structure is 100 μm or more.

3. The semiconductor package substrate of claim 1, wherein a thickness of the base layer corresponding to the groove structure is 35 μm or more.

4. The semiconductor package substrate of claim 1, wherein a width of the base layer with respect to the first surface corresponding to the groove structure is 30 μm or more greater than a width of the groove structure with respect to the second surface of the base layer.

5. The semiconductor package substrate of claim 1, further comprising:
a coating layer disposed on a surface of the base layer except for the first resin.

6. The semiconductor package substrate of claim 1, wherein at least a portion of the first resin is exposed to the outside through the groove structure.

7. The semiconductor package substrate of claim 1, further comprising:
a second resin buried in the second groove or second trench in the second surface of the base layer.

8. The semiconductor package substrate of claim 7, wherein a width of the base layer with respect to the first surface corresponding to the groove structure is the same as a width of the groove structure with respect to the second surface.

9. A semiconductor package comprising:
the semiconductor package substrate of any one of claims 1 through 8; and
a semiconductor chip mounted on the semiconductor package substrate.

10. A method of manufacturing a semiconductor package substrate, the method comprising:
preparing a base layer of a conductive material having a first surface and a second surface;
forming a first groove or first trench in the first surface of the base layer;
filling the first groove or first trench with a first resin;
curing the first resin;
removing a portion of the first resin that is exposed to the outside of the first groove or first trench and overfilled;
forming a second groove or second trench in the second surface of the base layer to expose at least a portion of the first resin filled in the first groove or first trench;
forming a third groove in the first surface of the base layer; and
cutting the base layer along a cutting area passing through the center of the third groove, wherein a depth of the third groove is at least 1/2 of a thickness of the base layer.

11. The method of claim 10, wherein the forming of the second groove or second trench in the base layer is simultaneously performed with the forming of the third groove.

12. The method of claim 10, wherein the third groove has a width in a first direction and a length in a second direction intersecting with the first direction, and
a width of a cutting area is less than a length of the third groove.

13. The method of claim 10, wherein the third groove has a depth of 100 μm or more.

14. The method of claim 10, wherein the thickness of the base layer corresponding to the third groove is 35 μm or more.

15. The method of claim 10, wherein a width of the base layer corresponding to the third groove as viewed from the second surface is equal to or greater than a width of the third groove as viewed from the first surface with respect to one side.

16. The method of claim 10, wherein at least a portion of the first resin is exposed to the outside through the third groove.

17. The method of claim 10, further comprising:
filling the second groove or second trench with a second resin between the forming of the second groove or second trench in the second surface of the base layer and the forming of the third groove in the first surface of the base layer, to expose at least a portion of the first resin filled in the first groove or first trench.

18. The method of claim 17, wherein a width of the base layer with respect to the first surface corresponding to the third groove is the same as a width of the third groove with respect to the second surface.

19. The method of claim 10, further comprising:
forming a coating layer by plating a surface of the base layer exposed through the first surface and the second surface between the forming of the third groove in the first surface of the base layer and cutting the base layer along a cutting area passing through the center of the third groove.

20. A method of manufacturing a semiconductor package, the method comprising:
preparing a base layer of a conductive material having a first surface and a second surface;
forming a first groove or first trench in the first surface of the base layer;
filling the first groove or first trench with a first resin;
curing the first resin;
removing a portion of the first resin that is exposed to the outside of the first groove or first trench and overfilled;
forming a second groove or second trench in the second surface of the base layer to expose at least a portion of the first resin filled in the first groove or first trench;
forming a third groove in the first surface of the base layer;
mounting a semiconductor chip on a semiconductor package substrate; and
cutting the semiconductor package substrate along the third groove,
wherein a depth of the third groove is at least ½ of a thickness of the base layer.
